(19) United States
(12) Patent Application Publication
(10) Pub. No.: US 2026/0177593 A1
(43) Pub. Date: Jun. 25, 2026

(54) VOLTAGE MONITORING CIRCUIT

(71) Applicant: KABUSHIKI KAISHA TOYOTA JIDOSHOKKI, Aichi-ken (JP)

(72) Inventors: Hayato UCHIDA, Kariya-shi (JP); Keiji YASHIRO, Kariya-shi (JP)

(73) Assignee: KABUSHIKI KAISHA TOYOTA JIDOSHOKKI, Aichi-ken (JP)

(21) Appl. No.: 19/418,251

(22) Filed: Dec. 12, 2025

(30) Foreign Application Priority Data
Dec. 20, 2024 (JP) 2024-224709

(51) Int. Cl. G01R 19/165; G01R 15/04

(52) U.S. Cl. CPC G01R 19/16576; G01R 15/04

(57) ABSTRACT

A voltage monitoring circuit includes a voltage-divider circuit, a first processing circuitry, a first filter, a second processing circuitry, and a second filter. The voltage-divider circuit includes a first voltage-divider resistor, a second voltage-divider resistor connected in series to the first voltage-divider resistor, a third voltage-divider resistor, and a fourth voltage-divider resistor connected in series to the third voltage-divider resistor. A connection point between the first and second voltage-divider resistors is a first connection point. A connection point between the third and fourth voltage-divider resistors is a second connection point. The second processing circuitry is configured to determine that an abnormality has occurred in the voltage-divider circuit when a difference between input voltages measured based on voltages input from the first connection and second connection points is greater than or equal to a threshold value.

### CROSS-REFERENCE TO RELATED APPLICATIONS

This application is based upon and claims the benefit of priority from Japanese Patent Application No. 2024-224709, filed on December 20, 2024, the entire contents of which are incorporated herein by reference.

### BACKGROUND

### 1. Field

The present disclosure relates to a voltage monitoring circuit.

### 2. Description of Related Art

JP2014-166108A discloses a voltage monitoring circuit that monitors an output voltage of a DC/DC converter. The voltage divided by the voltage-divider circuit is input to the voltage monitoring circuit. The voltage monitoring circuit monitors the output voltage by determining whether the input voltage exceeds a threshold value.

When an abnormality occurs in the voltage-divider circuit, the voltage monitoring circuit cannot monitor the output voltage.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the present disclosure provides a voltage monitoring circuit that includes a voltage-divider circuit connected to a power supply, first processing circuitry configured to determine whether an input voltage is an overvoltage, the input voltage being input from the power supply, a first filter located between the voltage-divider circuit and the first processing circuitry, second processing circuitry configured to measure the input voltage that is input from the power supply, and a second filter located between the voltage-divider circuit and the second processing circuitry. The voltage-divider circuit includes a first voltage-divider resistor for overvoltage detection, the first voltage-divider resistor being connected to the power supply, a second voltage-divider resistor for overvoltage detection, the second voltage-divider resistor being connected in series to the first voltage-divider resistor, a third voltage-divider resistor for voltage measurement, the third voltage-divider resistor being connected to the power supply, a fourth voltage-divider resistor for voltage measurement, the fourth voltage-divider resistor being connected in series to the third voltage-divider resistor. A connection point between the first voltage-divider resistor and the second voltage-divider resistor is a first connection point. A connection point between the third voltage-divider resistor and the fourth voltage-divider resistor is a second connection point. The first processing circuitry is configured to determine whether the input voltage that is input from the power supply is an overvoltage by comparing a voltage that is input from the first connection point via the first filter with a reference value. The second processing circuitry is configured to measure the input voltage that is input from the power supply based on the voltage that is input from the first connection point via the first filter, measure the input voltage that is input from the power supply based on a voltage that is input from the second connection point via the second filter, and determine that an abnormality has occurred in the voltage-divider circuit when a difference between the input voltage that has been measured based on the voltage that is input from the first connection point and the input voltage that has been measured based on the voltage that is input from the second connection point is greater than or equal to a threshold value.

Other features and aspects will be apparent from the following detailed description, the drawings, and the claims.

### BRIEF DESCRIPTION OF THE DRAWINGS

FIG. 1 is a circuit diagram of a voltage monitoring circuit.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment of a voltage monitoring circuit will now be described.

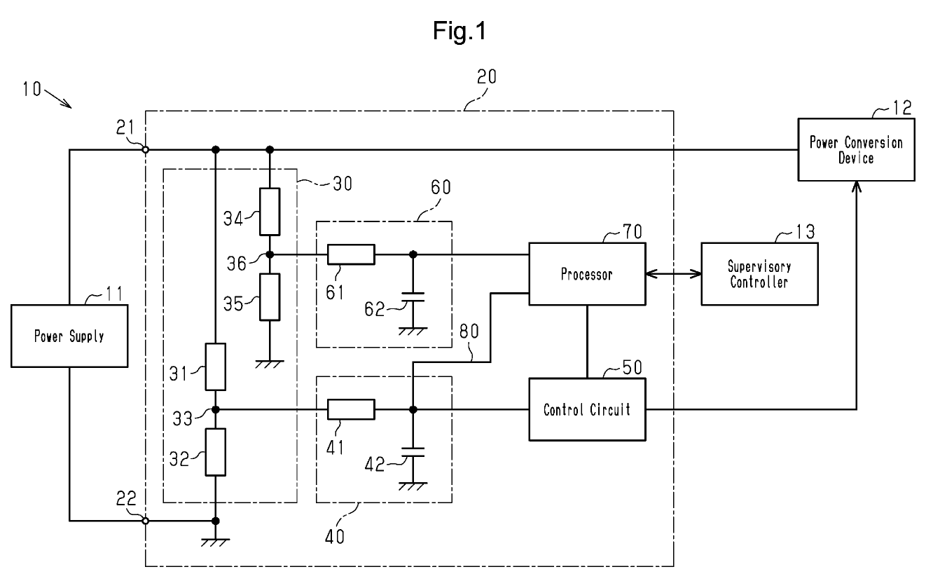

As shown in FIG. 1, a vehicle 10 includes a power supply 11, a power conversion device 12, a supervisory controller 13, and a voltage monitoring circuit 20.

The power supply 11 is a DC power supply. The power supply 11 is, for example, a battery.

The power conversion device 12 converts power that is input from the power supply 11, and outputs the converted power. The power conversion device 12 is, for example, an inverter that converts DC power into AC power and outputs the AC power. The power that has been output from the power conversion device 12 is supplied to, for example, a motor. The motor is, for example, a motor of a motor-driven compressor.

### Voltage Monitoring Circuit

The voltage monitoring circuit 20 includes a first input terminal 21 and a second input terminal 22. The first input terminal 21 is connected to a positive electrode of the power supply 11. The second input terminal 22 is connected to a negative electrode of the power supply 11.

The voltage monitoring circuit 20 includes a voltage-divider circuit 30, a first filter 40, a control circuit 50, a second filter 60, a processor 70, and a wire 80. The voltage-divider circuit 30 includes two voltage-divider resistors 31 and 32 for overvoltage detection and two voltage-divider resistors 34 and 35 for voltage measurement. The two voltage-divider resistors 31 and 32 for overvoltage detection include a first voltage-divider resistor 31 connected to the power supply 11 via the first input terminal 21 and a second voltage-divider resistor 32 connected in series to the first voltage-divider resistor 31. A resistance value R1 of the first voltage-divider resistor 31 and a resistance value R2 of the second voltage-divider resistor 32 may be the same or different.

The two voltage-divider resistors 34 and 35 for voltage measurement include a third voltage-divider resistor 34 connected to the power supply 11 via the first input terminal 21 and a fourth voltage-divider resistor 35 connected in series to the third voltage-divider resistor 34. A resistance value R3 of the third voltage-divider resistor 34 and a resistance value R4 of the fourth voltage-divider resistor 35 may be the same or different.

The first filter 40 is a low-pass filter. The first filter 40 includes a first resistor 41 and a first capacitor 42. The first resistor 41 is connected to a first connection point 33 that is between the first voltage-divider resistor 31 and the second voltage-divider resistor 32. The first capacitor 42 is located between the first resistor 41 and the ground.

The control circuit 50 may include a processor and a memory. The processor is, for example, a central processing unit (CPU), a graphics processing unit (GPU), or a digital signal processor (DSP). The memory includes a random-access memory (RAM) and a read-only memory (ROM). The memory stores a program for operating the control circuit. The memory stores program codes or instructions configured to cause the processor to execute processes. The memory, which is a computer-readable medium, includes any type of medium that is accessible by a general-purpose computer or a dedicated computer. The control circuit 50 may include a hardware circuit such as an application-specific integrated circuit (ASIC) or a field-programmable gate array (FPGA). The control circuit 50, which is first processing circuitry, may include one or more processors that operate in accordance with a computer program, one or more hardware circuits such as ASICs or FPGAs, or a combination thereof.

For example, the control circuit 50 is an integrated circuit. The control circuit 50 controls the power conversion device 12 and detects an overvoltage. The control circuit 50 controls the power conversion device 12 by, for example, outputting a drive signal to a drive circuit that drives the power conversion device 12.

The first filter 40 is connected to the control circuit 50. Specifically, the first resistor 41 is connected to the control circuit 50. As a result, a voltage is input from the first connection point 33 to the control circuit 50 via the first filter 40, which is located between the voltage-divider circuit 30 and the control circuit 50. A voltage V1 that is input from the first connection point 33 is a voltage that has been divided by the first voltage-divider resistor 31 and the second voltage-divider resistor 32. The voltage V1, which is input from the first connection point 33, can be expressed by the resistance value R2 × an input voltage Vin / (the resistance value R1 + the resistance value R2). The input voltage Vin is input from the power supply 11.

The control circuit 50 determines whether the input voltage Vin is an overvoltage by comparing the voltage V1 with a reference value. The overvoltage indicates a state in which the input voltage Vin is greater than an allowable value. The voltage V1 is lower than the input voltage Vin due to voltage division. The reference value may be set so as to determine, from the voltage V1, whether the input voltage Vin is greater than the allowable value based on the resistance value R1 and the resistance value R2. When the voltage V1 is higher than the reference value as a result of the comparison between the voltage V1 and the reference value, the control circuit 50 determines that the input voltage Vin is an overvoltage. When the voltage V1 is less than or equal to the reference value as a result of the comparison between the voltage V1 and the reference value, the control circuit 50 determines that the input voltage Vin is not an overvoltage. Thus, the control circuit 50 detects an overvoltage. When determining that the input voltage Vin is an overvoltage, the control circuit 50 stops the power conversion device 12. Further, the control circuit 50 notifies the processor 70 that the input voltage Vin is an overvoltage. The control circuit 50 is an example of an overvoltage determination unit.

The second filter 60 is a low-pass filter. The second filter 60 includes a second resistor 61 and a second capacitor 62. The second resistor 61 is connected to a second connection point 36 that is between the third voltage-divider resistor 34 and the fourth voltage-divider resistor 35. The second capacitor 62 is located between the second resistor 61 and the ground. The cutoff frequency of the second filter 60 is lower than the cutoff frequency of the first filter 40. Thus, the time constant of the first filter 40 is smaller than the time constant of the second filter 60.

The processor 70, which is second processing circuitry, is, for example, a CPU, a micro processing unit (MPU), or a digital signal processor (DSP). The processor 70 communicates with the supervisory controller 13, issues a command to the control circuit 50, and measures the input voltage Vin.

The processor 70 transmits and receives information by communicating with the supervisory controller 13. For example, the processor 70 receives a command from the supervisory controller 13. The processor 70 transmits the states of the power conversion device 12 and the voltage monitoring circuit 20 to the supervisory controller 13.

The processor 70 issues a command to the control circuit 50 in response to a command from the supervisory controller 13. Examples of the command to the control circuit 50 include a drive command to the power conversion device 12 or a stop command to the power conversion device 12. The control circuit 50 controls the power conversion device 12 in response to a command from the processor 70.

The wire 80 connects a wire extending between the voltage-divider circuit 30 and the control circuit 50 to the processor 70. Specifically, the wire 80 connects the connection point between the first resistor 41 and the first capacitor 42 to the processor 70. Accordingly, the voltage V1 is input from the first connection point 33 to the processor 70 via the first filter 40, which is located between the voltage-divider circuit 30 and the control circuit 50. The first filter 40 also serves as a filter disposed between the first connection point 33 and the processor 70. The wire 80 that branches from the wire extending between the first filter 40 and the control circuit 50 is connected to the processor 70 such that a voltage from which noise has been removed by the first filter 40 is input to the processor 70.

### Abnormality Determination for Voltage-Divider Circuit

The processor 70 measures the input voltage Vin based on the voltage V1. The input voltage Vin can be expressed by the voltage V1 × (the resistance value R1 + the resistance value R2) / the resistance value R2. The resistance values R1 and R2 are stored in a memory readable by the processor 70. This allows the processor 70 to measure the input voltage Vin based on the voltage V1.

The second filter 60 is connected to the processor 70. Specifically, the second resistor 61 is connected to the processor 70. Accordingly, a voltage is input from the second connection point 36 to the processor 70 via the second filter 60, which is located between the voltage-divider circuit 30 and the processor 70. A voltage V2 that is input from the second connection point 36 is a voltage that has been divided by the third voltage-divider resistor 34 and the fourth voltage-divider resistor 35. The voltage V2, which is input from the second connection point 36, can be expressed by the resistance value R4 × the input voltage Vin / (the resistance value R3 + the resistance value R4).

The processor 70 measures the input voltage Vin based on the voltage V2. The input voltage Vin can be expressed by the voltage V2 × (the resistance value R3 + the resistance value R4) / the resistance value R4. The resistance values R3 and R4 are stored in a memory readable by the processor 70. This allows the processor 70 to measure the input voltage Vin based on the voltage V2.

The processor 70 determines that an abnormality has occurred in the voltage-divider circuit 30 by comparing the input voltage Vin that has been measured based on the voltage V1, which is input from the first connection point 33, with the input voltage Vin that has been measured based on the voltage V2, which is input from the second connection point 36. The input voltage Vin that has been measured based on the voltage V1, which is input from the first connection point 33, may be referred to as a first input voltage. The input voltage Vin that has been measured based on the voltage V2, which is input from the second connection point 36, may be referred to as a second input voltage.

When the difference between the first input voltage and the second input voltage is greater than or equal to the threshold value, the processor 70 determines that an abnormality has occurred in the voltage-divider circuit 30. When the difference between the first input voltage and the second input voltage is less than the threshold value, the processor 70 determines that no abnormality has occurred in the voltage-divider circuit 30. The processor 70 may use, as the difference between the first input voltage and the second input voltage, the difference between the average value of the first input voltage measured a number of times and the average value of the second input voltage measured a number of times.

An abnormality in the voltage-divider circuit 30 is a short circuit or an open circuit in at least one of the four voltage-divider resistors 31, 32, 34, and 35. A short circuit or an open circuit in at least one of the four voltage-divider resistors 31, 32, 34, and 35 results in a difference between the first input voltage and the second input voltage. Thus, the processor 70 detects an abnormality in the voltage-divider circuit 30 by comparing the first input voltage with the second input voltage. The threshold value only needs to be larger than the difference between the first input voltage and the second input voltage that may occur when no abnormality has occurred in the voltage-divider circuit 30. The phrase 'at least one of' as used in this specification means one or more from the desired options. For example, if there are two options, the phrase 'at least one of' as used in this specification means either a single option or both options. As another example, if there are three or more options, the phrase 'at least one of' as used in this specification means a single option or any combination of two or more options therefrom.

When determining that an abnormality has occurred in the voltage-divider circuit 30, the processor 70 stops the driving of the power conversion device 12 by transmitting a stop command to the control circuit 50. The processor 70 notifies the supervisory controller 13 that an abnormality has occurred. The supervisory controller 13 may notify the user of the vehicle 10 that an abnormality has occurred. The processor 70 is an example of a voltage measurement unit.

### Operation of the Present Embodiment

The control circuit 50 controls the power conversion device 12. The power conversion device 12 converts power that has been input from the power supply 11, and outputs the converted power. The control circuit 50 detects an overvoltage by comparing the voltage V1, which is input from the first connection point 33, with the reference value and notifies the processor 70 upon detecting an overvoltage. The processor 70 measures the input voltage Vin from the voltage V2, which is input from the second connection point 36.

When the short circuit or an open circuit occurs in the voltage-divider resistor 31 or 32 for overvoltage detection, the input voltage Vin is not divided by the voltage-divider resistors 31 and 32 for overvoltage detection. In this case, it cannot be correctly determined whether an overvoltage has occurred. When a short circuit or an open circuit occurs in the voltage-divider resistor 34 or 35 for voltage measurement, the input voltage Vin is not divided by the voltage-divider resistors 34 and 35 for voltage measurement. In this case, the input voltage Vin cannot be correctly measured.

An abnormality in the voltage-divider circuit 30 results in a difference between the input voltage Vin that has been measured based on the voltage V1, which is input from the first connection point 33, and the input voltage Vin that has been measured based on the voltage V2, which is input from the second connection point 36. Thus, when the difference between the input voltage Vin that has been measured based on the voltage V1, which is input from the first connection point 33, and the input voltage Vin that has been measured based on the voltage V2, which is input from the second connection point 36, is greater than or equal to the threshold value, it is determined that an abnormality has occurred in the voltage-divider circuit 30.

### Advantages of the Present Embodiment

(1) The wire 80 is provided to input the voltage of the first connection point 33 to the processor 70. This allows the processor 70 to measure the input voltage Vin from each of the voltage V1, which is input from the first connection point 33, and the voltage V2, which is input from the second connection point 36. When no abnormality has occurred in the voltage-divider circuit 30, the difference between the first input voltage and the second input voltage is less than the threshold value. When an abnormality has occurred in the voltage-divider circuit 30, one of the first input voltage and the second input voltage cannot be correctly measured. In this case, the difference between the first input voltage and the second input voltage is greater than or equal to the threshold value. This allows the processor 70 to determine that an abnormality has occurred in the voltage-divider circuit 30.

(2) The output of the voltage-divider resistors 31 and 32 for overvoltage detection is split by the wire 80. This allows the processor 70 to measure the input voltage Vin using the voltage-divider resistors 31 and 32 for overvoltage detection. That is, the voltage-divider resistors 31 and 32 for overvoltage detection also serve as a voltage-divider resistor for measuring the input voltage Vin. Thus, compared with when a new voltage-divider resistor for measuring the input voltage Vin is disposed to detect an abnormality in the voltage-divider circuit 30, an increase in the size of the voltage monitoring circuit 20 is limited.

(3) The wire 80 is connected to the wire extending between the first filter 40 and the control circuit 50 such that the voltage V1 from which noise has been removed by the first filter 40 is input to the processor 70. Thus, as compared with when a filter is disposed to remove noise from the voltage V1, which is input from the first connection point 33 to the processor 70, an increase in the size of the voltage monitoring circuit 20 is limited.

(4) The time constant of the first filter 40 is smaller than the time constant of the second filter 60. Thus, the first filter 40 is used to increase the speed of detecting an overvoltage. The noise contained in the voltage V1, which is input from the first connection point 33 to the processor 70, may be larger than the noise contained in the voltage V2, which is input from the second connection point 36 to the processor 70. With the above-described configuration, the processor 70 uses the difference between the average value of the first input voltage and the average value of the second input voltage as the difference between the first input voltage and the second input voltage, thereby reducing the influence of noise.

(5) The processor 70 notifies the supervisory controller 13 when an abnormality has occurred in the voltage-divider circuit 30. This allows the supervisory controller 13 to respond to an abnormality in the voltage-divider circuit 30 (e.g., notify the user).

### Modifications

The embodiment may be modified as follows. The embodiment and the following modifications can be combined as long as the combined modifications remain technically consistent with each other.

The wire 80 may connect the wire extending between the first connection point 33 and the first filter 40 to the processor 70. In this case, a dedicated filter only needs to disposed to remove noise from the voltage V1, which is input from the first connection point 33 to the processor 70.

The processor 70 does not have to notify the supervisory controller 13 when an abnormality has occurred in the voltage-divider circuit 30.

The time constant of the first filter 40 may be equal to the time constant of the second filter 60.

The voltage monitoring circuit 20 may be located in any device as long as it can monitor the input voltage Vin from the power supply 11.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A voltage monitoring circuit, comprising:
a voltage-divider circuit connected to a power supply;
first processing circuitry configured to determine whether an input voltage is an overvoltage, the input voltage being input from the power supply;
a first filter located between the voltage-divider circuit and the first processing circuitry;
second processing circuitry configured to measure the input voltage that is input from the power supply; and
a second filter located between the voltage-divider circuit and the second processing circuitry, wherein
the voltage-divider circuit includes:
a first voltage-divider resistor for overvoltage detection, the first voltage-divider resistor being connected to the power supply;
a second voltage-divider resistor for overvoltage detection, the second voltage-divider resistor being connected in series to the first voltage-divider resistor;
a third voltage-divider resistor for voltage measurement, the third voltage-divider resistor being connected to the power supply; and
a fourth voltage-divider resistor for voltage measurement, the fourth voltage-divider resistor being connected in series to the third voltage-divider resistor,
a connection point between the first voltage-divider resistor and the second voltage-divider resistor is a first connection point,
a connection point between the third voltage-divider resistor and the fourth voltage-divider resistor is a second connection point,
the first processing circuitry is configured to determine whether the input voltage that is input from the power supply is an overvoltage by comparing a voltage that is input from the first connection point via the first filter with a reference value, and
the second processing circuitry is configured to:
measure the input voltage that is input from the power supply based on the voltage that is input from the first connection point via the first filter;
measure the input voltage that is input from the power supply based on a voltage that is input from the second connection point via the second filter; and
determine that an abnormality has occurred in the voltage-divider circuit when a difference between the input voltage that has been measured based on the voltage that is input from the first connection point and the input voltage that has been measured based on the voltage that is input from the second connection point is greater than or equal to a threshold value.

2. The voltage monitoring circuit according to claim 1, wherein
a wire branching from a wire extending between the first filter and the first processing circuitry is connected to the second processing circuitry such that a voltage from which noise has been removed by the first filter is input to the second processing circuitry.

3. The voltage monitoring circuit according to claim 1, wherein
the second processing circuitry is configured to notify a supervisory controller when determining that an abnormality has occurred in the voltage-divider circuit.
